(19) United States
(12) Patent Application Publication
(10) Pub. No.: US 2013/0314989 A1
(43) Pub. Date: Nov. 28, 2013

(54) MEMORY SYSTEM

(71) Applicant: KABUSHIKI KAISHA TOSHIBA, Tokyo (JP)

(72) Inventors: Mio Wakisaka, Mie (JP); Shigefumi Irieda, Kanagawa (JP)

(73) Assignee: Kabushiki Kaisha Toshiba, Tokyo (JP)

(21) Appl. No.: 13/784,498

(22) Filed: Mar. 4, 2013

(30) Foreign Application Priority Data
May 25, 2012 (JP) 2012-120118

(51) Int. Cl. G11C 16/10

(52) U.S. Cl. CPC G11C 16/10
USPC 365/185.03

(57) ABSTRACT

A memory system includes nonvolatile memory cells each configured to store more than one bit of data, dummy memory cells adjacent to the nonvolatile memory cells, and a control section that applies a read voltage to the nonvolatile memory cells while a first voltage is applied to a gate of the dummy memory cells, when data of the nonvolatile memory cells are read out. The first voltage is higher than a second voltage for turning on the nonvolatile memory cells whose data are not read during the read out.

### CROSS-REFERENCE TO RELATED APPLICATION

This application is based upon and claims the benefit of priority from Japanese Patent Application No. 2012-120118, filed May 25, 2012; the entire contents of which are incorporated herein by reference.

### FIELD

Embodiments described herein relate generally to a memory system and more particularly to a memory system including a semiconductor memory, e.g., an NAND type flash memory.

### BACKGROUND

The demand for NAND type flash memories has been rapidly increasing along with the increase in processing large-size data such as images and dynamic images in mobile appliances. With the adoption of a multi-valued memory technique that can store information of two bits or more in one memory cell, much more information can be stored.

### DESCRIPTION OF THE DRAWINGS

FIG. 1 shows a memory system of a first embodiment.

FIG. 2 is a circuit diagram showing a memory cell array of the first embodiment and a block diagram showing a sequencer, a page buffer, and a sense amplifier of the first embodiment.

FIGS. 3A and 3B show a threshold distribution of memory cells of the first embodiment.

FIG. 4 shows a circuit diagram of the sense amplifier of the first embodiment.

FIG. 5 is a flow chart showing a load sequence of the sequencer of the first embodiment.

FIG. 6 is a timing chart showing the load sequence of the sequencer of the first embodiment.

FIG. 7 is a flow chart showing a load sequence of a modified example of the sequencer of the first embodiment.

FIG. 8 is a flow chart showing a load sequence of another modified example of the sequencer of the first embodiment.

FIG. 9 shows a conversion table example of a sequencer of a second embodiment.

FIG. 10 is a flow chart showing a load sequence of the sequencer of the second embodiment.

FIGS. 11A and 11B show a threshold distribution of memory cells when data are written in an LM mode.

FIG. 12 shows a conversion table example of a modified example of the sequencer of the second embodiment.

FIG. 13 shows a conversion table example of another modified example of the sequencer of the second embodiment.

### DETAILED DESCRIPTION

Embodiments provide a memory system that can reduce the frequency of incorrect readout of data.

In general, embodiments will be described with reference to the figures. In the following explanation, common reference symbols are given to common elements across all of the figures. In addition, the figures are schematic, and it should be noted that the relationship between thickness and planar size, ratio of the thickness of each layer, etc., is different from actual ones.

The memory system of this embodiment includes nonvolatile memory cells each configured to store more than one bit of data, dummy memory cells adjacent to the nonvolatile memory cells, and a control section that applies a read voltage to a gate of the nonvolatile memory cells while a first voltage is applied to a gate of the dummy memory cells, when data of the nonvolatile memory cells are read out. The first voltage is higher than a second voltage for turning on the nonvolatile memory cells whose data are not read during the read out.

### First Embodiment

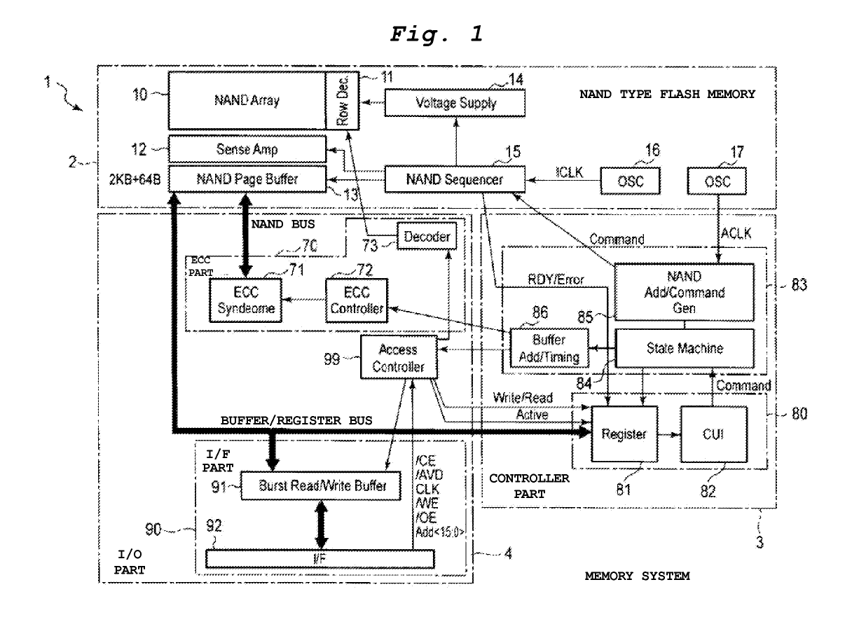

An example of the memory system of the first embodiment will be explained with reference to the block diagram of FIG. 1. For convenience of explanation, the memory system of this embodiment is explained as a memory system having a NAND type flash memory and a controller for controlling the memory; however this memory system is not limited thereto. For example, a memory system including an external host appliance in the NAND type flash memory and the controller may also be adopted. Here, the function of the controller may also be implemented by the external host appliance.

The memory system of this embodiment includes a system in which any of NAND type flash memory, controller, and external host appliance can be combined to achieve similar effects.

### 1. <Entire Constitutional Example>

An entire constitutional example of a memory system 1 of the first embodiment will be explained. As a detailed constitutional example, the memory system 1 is provided with an NAND type flash memory 2, an ECC part 70, and a controller part 3 for controlling them. In other words, in the following explanation, the construction including the NAND type flash memory 2, ECC part 70, and controller part 3 is assumed as the memory system.

As shown in the figure, the memory system 1 of this embodiment is mainly provided with the NAND type flash memory 2, controller part 3, and input/output part 4. These NAND type flash memory 2, controller part 3, and input/output part 4, for example, are formed on the same semiconductor substrate and integrated in one chip. Next, details of each block will be explained.

### 1.1<NAND Type Flash Memory 2>

The NAND type flash memory 2 functions as a main storage part of the memory system 1. As shown in FIG. 1, the NAND type flash memory 2 includes memory cell array (NAND array in the figure) 10, row decoder (Row Dec in the figure) 11, sense amplifier (Sense Amp in the figure) 12, page buffer (NAND Page Buffer in the figure) 13, voltage generating circuit (Voltage Supply in the figure) 14, sequencer (NAND Sequencer in the figure) 15, and oscillators (OSC in the figure) 16 and 17.

### 1.1.1<Memory Cell Array 10>

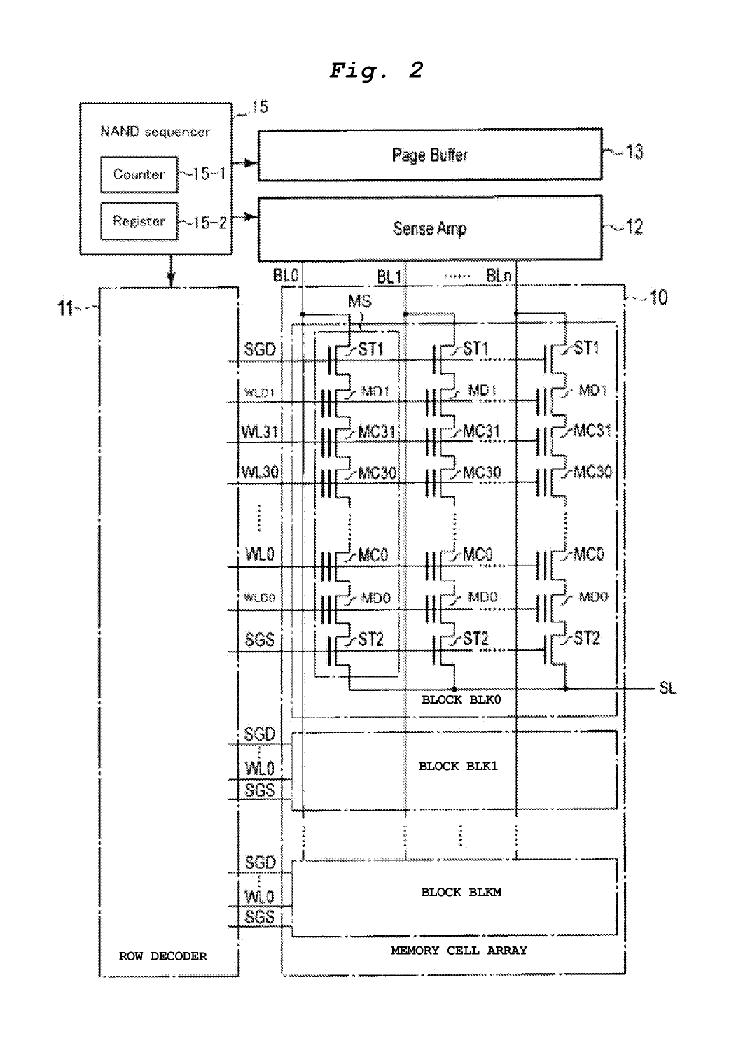

The memory cell array 10 has a function of storing data received from the outside and outputting the stored data to the outside. A detailed construction of the memory cell array 10 in the NAND type flash memory 2 will be explained with reference to a block diagram of FIG. 2. FIG. 2 is a circuit diagram showing the memory cell array 10 and a block diagram showing the row decoder 11, sequence amplifier 12, and page buffer 13.

As shown in FIG. 2, the memory cell array includes (m+1) pieces (m represents a natural number) of blocks BLK0-BLKm. Hereinafter, in case the blocks BLK0-BLKm are not respectively discriminated, they are simply called the blocks BLK. Each of the blocks BLK is provided with (n+1) pieces (n represents a natural number) of several memory strings MS.

Each of the memory string MS, for example, includes 32 pieces of memory cells MC0-MC31, selective transistors ST1 and ST2, and dummy memory cells MD0 and MD1. In the following, in case the memory cells MC0-MC31 are not discriminated, they are simply called the memory cells MC. The memory cells MC have a laminated gate structure including a charge storage layer (for example, floating gate) formed via a gate insulating film on a semiconductor substrate and a control gate formed via an insulating film on a charge storage layer. Here, the number of memory cells MC is not limited to 32 pieces but may also be 8 pieces, 16 pieces, 64 pieces, 128 pieces, 256 pieces, etc. The number is not limited. In addition, the memory cells MC may also have an MONOS (Metal Oxide Nitride Oxide Silicon) structure using an insulating film such as nitride film as the charge storage layer and a mode for trapping electrons in the nitride film.

Moreover, in case the dummy memory cells MD0 and MD1 are not discriminated, they are simply called the dummy memory cells MD. The dummy memory cells MD have the same structure as that of the memory cells MC. For example, in case the memory cells MC have a FG structure, the dummy memory cells MD also have the FG structure. The memory cells MC and the dummy memory cells MD are formed by a common process. The dummy memory cells MD are different from the memory cells MC in that data are usually not written in the dummy memory cells.

The adjacent memory cells MC share a source and a drain. Several memory cells MC are arranged between the dummy memory cells MD1 and MD0 so that their current path is serial. The selective transistors ST1 and ST2 are arranged so that they are respectively connected in series to the dummy memory cells MD1 and MD0. In other words, the drain at one end of several memory cells MC connected in series is connected to a source of the dummy memory cell MD1, and the source at the other end is connected to the drain of the dummy memory cell MD0. The drain of the dummy memory cell MD1 is connected to the source of the selective transistor ST1, and the source of the dummy memory cell MD0 is connected to the drain of the selective transistor ST2.

Control gates of the memory cells MC in the same row are commonly connected to one of word lines WL0-WL31. The dummy memory cell MD0 in the same row is commonly connected to the dummy word line WLD0. The dummy memory cell MD1 in the same row is commonly connected to the dummy word line WLD1.

Furthermore, the gates of the selective transistors ST1 and ST2 in the same row are respectively, commonly connected to selective gate lines SGD and SGS. Hereinafter, for simplicity of explanation, the word lines WL0-WL31 are sometimes called the word lines WL.

In addition, the drain of the selective transistor ST1 is connected to one of bit lines BL0-BLn. The bit lines BL0-BLn commonly connect several memory strings MS among several blocks BLK. In case the bit lines BL0-BLn are not discriminated, they are simply called the bit lines BL.

The source of the selective transistor ST2 is connected to a source line SL. The source line SL is commonly used in the memory cell array 10.

In the construction, data is collectively written into or read out of several memory cells MC connected to the same word line WL, and this unit is called a page. In addition, data is erased in units of blocks. In other words, the data of the memory cells, which are included in the same block, are collectively erased.

Each memory cell MC, for example, can store data of 1 bit (either “0” data or “1” data) in accordance with the change of a threshold voltage of transistors due to an amount of electrons injected into the charge storage layer. Here, a construction in which the control of the threshold voltage is finely divided and data of 2 bits or more are held in each memory cell MC may also be adopted. For example, if electric charges are accumulated in the charge storage layer, the memory cells MC store “0” data, and if these electric charges escape and an erasure state is set, the memory cells MC store “1” data.

In addition in each block BLK, some of the memory strings MS are used in storing information for error correction (e.g., parity), and the remaining memory strings MS are used for storing user data.

Moreover, a certain block BLK (for example, block BLKm in this embodiment) is used to store system information of the NAND type flash memory 2. An example of the system information is defective block information or defective column information. The defective block information identifies a block BLK that cannot be used because of certain defects, for example, by its block address. In the following, the block BLKm is sometimes called the ROM fuse block.

### 1.1.1.1<Threshold Distribution of Memory Cells MC>

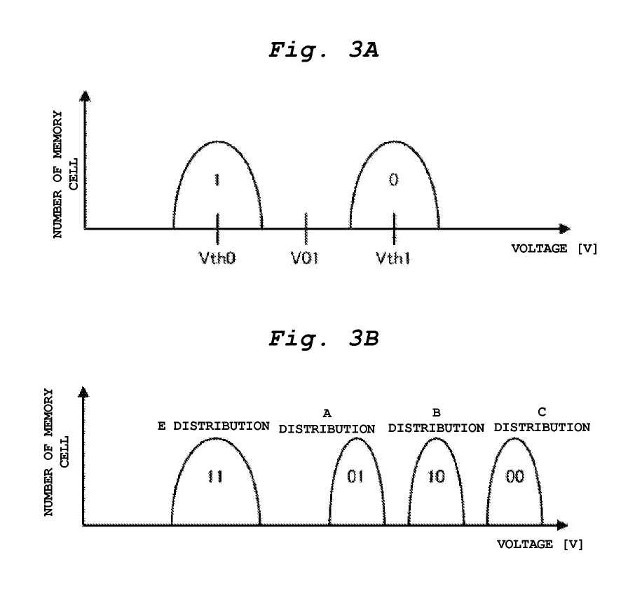

A threshold distribution of the memory cells MC will be explained with reference to FIG. 3A and FIG. 3B. FIG. 3A and FIG. 3B are graphs in which the abscissa indicates the threshold distribution (voltage) and the ordinate indicates the number of memory cells MC.

As shown in the figures, each memory cell MC, for example, can store binary (2-levels) data (1-bit data: two kinds of data of “1” and “0” in order of a low threshold voltage Vth). In addition, the memory cells MC are set to “1” data (for example, negative voltage) in an erasure state and, during a write, are set to a positive threshold voltage by injecting electric charges into the charge storage layer.

In FIG. 3A, the case where the memory cells MC have binary data is shown. However, as shown in FIG. 3B, in the memory cells MC having quaternary (2 bits) data, “11,” “01,” “10,” and “00” data are identified by four threshold distributions. For convenience of explanation, the threshold distribution of the erasure state is assumed as E distribution, and A distribution, B distribution, and C distribution are ordered according to their threshold voltage Vth.

### 1.1.2<Row Decoder 11>

Next, the row decoder 11 will be explained with reference to FIG. 1 and FIG. 2. The row decoder 11 selects word lines and selective gate lines at a time of program operation, load operation, and erasure operation. The row decoder 11 transfers a required voltage (voltage VPGM, voltage VPASS, voltage Vcgr, voltage Vread, voltage Vera, etc.) to the word lines and the selective gate lines.

### 1.1.3<Sense Amplifier 12>

The sense amplifier 12 can store data one page at a time. At a time of a load operation, the sense amplifier 12, for example, senses data by detecting and amplifying a cell current flowing in the bit lines BL of one page connected to the memory cells to be loaded and transfers the sensed data to the page buffer 13. At a time of a programming operation, the sense amplifier 12 receives data (also including ECC parity) one page at a time from the page buffer 13 and transfers a desired voltage to the bit lines BL in accordance with the data of each bit.

The load operation is an operation that reads data out of the NAND type flash memory 2 and outputs the data to the output part 4. In addition, the operation until data read out of the memory cell array 10 are transferred to an interface part 90 is called “read” of the data.

The sense amplifier 12 is not limited to the case where a cell current is detected and amplified to detect data but may be a pattern in which data are sensed by detecting the voltage of bit lines, for instance.

### 1.1.3.1<Detailed Construction Example of Sense Amplifier>

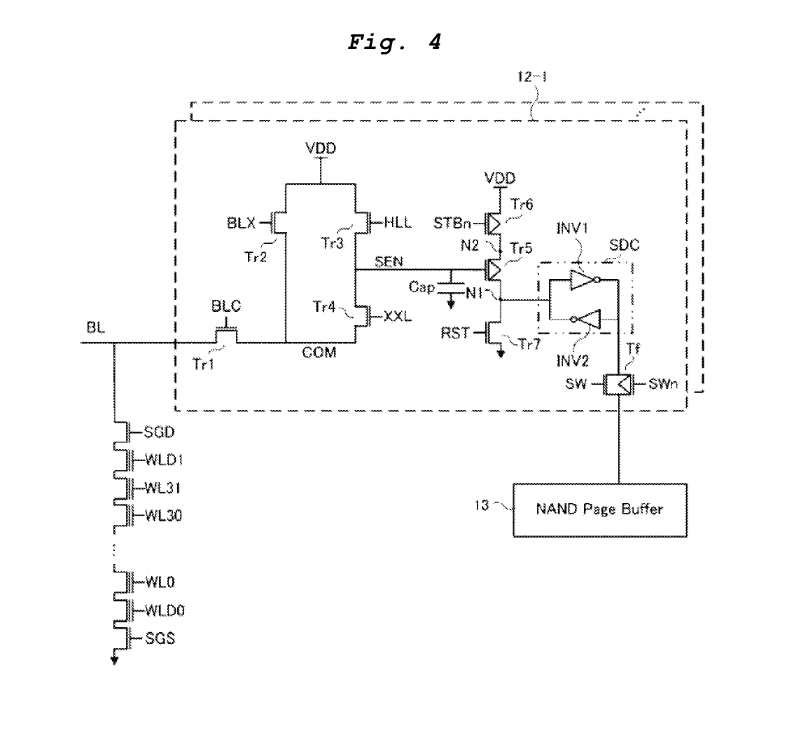

Next, a detailed construction example of the sense amplifier 12 will be explained with reference to FIG. 4. FIG. 4 shows a circuit diagram of a sense unit that is implemented in the sense amplifier 12 of the first embodiment.

The sense amplifier 12 of this embodiment has several sense units 12-1. The sense unit 12-1 is installed for each bit line BL.

The sense unit 12-1 has several MOS transistors Tr1-Tr7, capacitor Cap, latch circuit SDC, and transfer gate Tf. The MOS transistors Tr1-Tr4 and Tr7 are N channel type MOS transistors, and Tr5 and Tr6 are P channel type MOS transistors.

One end of a current path of the MOS transistor Tr1 is connected to the bit line BL, and a signal BLC, which is controlled by the sequencer 15, is supplied to its gate. The signal BLC is a signal that is set to “H” level at the time of the load operation and the program operation and can connect to the bit line BL and the sense unit 12-1.

One end of a current path of the MOS transistor Tr2 is connected to the other end of the current path of the MOS transistor Tr1, the other end is connected to a power source VDD, and a signal BLX, which is controlled by the sequencer 15, is supplied to its gate.

One end of a current path of the MOS transistor Tr3 is connected to a node SEN, the other end is connected to a power source VDD commonly to the other end of the MOS transistor Tr2, and a signal HLL, which is controlled by the sequencer 15, is supplied to its gate. One end of a current path of the MOS transistor Tr4 is connected to a node SEN, the other end is connected to the other end of the MOS transistor Tr1 commonly to one end of the MOS transistor Tr2, and a signal XXL, which is controlled by the sequencer 15, is supplied to its gate.

One end of a capacitor Cap is connected to a ground Vss, and the other end is connected to the node SEN.

One end of a current path of the MOS transistor Tr5 is connected to a node N1, the other end is connected to a node N2, and the node SEN is connected to its gate. One end of a current path of the MOS transistor Tr6 is connected to the power source VDD, the other end is connected to the node N2, and a signal STBn, which is controlled by the sequencer 15, is supplied to its gate. One end of a current path of the MOS transistor Tr7 is connected to the ground Vss, the other end is connected to the node N1, and a signal RST, which is controlled by the sequencer 15, is supplied to its gate. Here, the signal RST is a signal for resetting data of the latch circuit SDC which will be described later.

The latch circuit SDC has two inverters INV1 and INV2. In addition, one end of the transfer gate Tf is connected to the latch circuit SDC, the other end is connected to the page buffer 13, and signals SW and SWn are input into its gate. Here, the signal SWn is an inverted signal of the signal SW.

### 1.1.4<Page Buffer 13>

Next, the page buffer 13 will be explained with reference to FIG. 1 and FIG. 2. At the time of the program operation, the page buffer 13 can store one page of data, temporarily store data, which are transferred from the input/output part 4, and transfers the data to the sense amplifier 12. On the other hand, at the time of the load operation, the page buffer temporarily stores data read and transferred by the sense amplifier 12, applies a correction processing to the data by the ECC part 70, and transfers the corrected data to the input/output part 4.

### 1.1.5<Voltage Generating Circuit 14>

The voltage generating circuit 14 steps up or steps down a voltage, which is applied from the outside, to generate a voltage (voltage VPGM, voltage VPASS, voltage Vcgr, voltage Vread, voltage Vera, etc.) required for program, load, and erasure of data. Next, the voltage generated, for example, is supplied to the row decoder 11. Therefore, the voltage generated by the voltage generating circuit 14 is applied via the row decoder 11 to the word lines WL. The voltage generating circuit 14, for example, includes several pumps.

### 1.1.6<Sequencer 15>

The sequencer 15 is in charge of the entire operation of the NAND type flash memory 2. In other words, if program instruction (Program), load instruction (Load), or erasure instruction (not shown in the figure) are received from the controller part 3, a sequence for program, load, and erasure of data is implemented in response to the instructions. The sequencer 15 controls the operations of the sense amplifier 12, voltage generating circuit 14, and page buffer 13 according to this sequence.

The operation until data to be stored in the NAND type flash memory 2 are transferred to the input/output part 4 is called “write” of the data. In addition, the operation until data in the page buffer 13 are written into the memory cell array 10 is called “program” of the data.

When data is loaded from the memory cell MCk (k=0−30) (load operation), the sequencer 15 of this embodiment controls the operation of the row decoder 11 and the voltage generating circuit 14 so that a first pass voltage is applied to the word line WL(k+1) that are connected to the adjacent memory cells MC(k+1). Here, the first pass voltage is higher than a second pass voltage. The second pass voltage is a pass voltage Vread, which is a conductive voltage at which the memory cells MC are set to an on-state.

In addition, when data is loaded from the memory cell MC31 (load operation), the sequencer 15 controls the operation of the row decoder 11 and the voltage generating circuit 14 so that the first pass voltage is applied to the gate (dummy word line WL1) of the dummy memory cell MD1 adjacent to the memory cell MC31. More specifically, when the row decoder 11 selects the word line WL31, the sequencer 15 controls the row decoder 11 so to that the dummy word lines WLD1 connected to the dummy memory cell MD1 is electrically connected with the pump (voltage generating circuit 14) for first pass voltage generation. As a result, at the time of the load operation, the desired first pass voltage is applied to the dummy word lines WLD1.

The sequencer 15, for example, is operated based on a sequence code held in a peripheral circuit not shown in the figure. In this sequence code, a control operation for applying the first pass voltage to the adjacent word lines WL(k+1), when data of the memory cell MCk is loaded, and when applying the first pass voltage to the dummy word line WLD1 when data of the memory cell MC31 are loaded.

Moreover, the sequencer 15 has a counter 15-1 and a register 15-2. The counter 15-1 sets an erasure operation and a program operation once for each block and counts the number of repetition of the erasure operation and the program operation (the number of repetition). Next, the count value of the block BLKi of the counter 15-1 will be explained as Ci (i represents a natural number from 0 to m). In other words, the erasure operation and the program operation are repeated Ci times.

The register 15-2 can store a prescribed value showing the reliability of memory cells. For example, in case the erasure operation and the program operation are repeated n times, if the reliability of the memory cells is markedly lowered, the value n is held as a prescribed value. The definition of the prescribed value is not limited to this case. For example, even in case the erasure state and the program operation may be repeated n times, if the reliability of the memory cells is not changed from the reliability in an initial state, the value n may be stored as the prescribed value. The prescribed value may be determined as an index for the reliability of the memory cells, and its definition is not uniform but can be changed for each user and each product.

This prescribed value, for example, is a value preset by a die sort test. The prescribed value is stored in a ROM fuse block in the memory cell array 10. When the power of the NAND type flash memory is turned on, the prescribed value is read out of the ROM fuse block and set in the sequencer 15.

Next, this embodiment will be explained, assuming that the value n is stored in the register 15-2.

### 1.1.7<Oscillator 16>

The oscillator 16 generates an internal block ICLK. In other words, this oscillator functions as a clock generator. The oscillator 16 supplies the generated internal block ICLK to the sequencer 15. The sequencer 15 is operated synchronously with the internal clock ICLK.

### 1.1.8<Oscillator 17>

The oscillator 17 generates an internal clock ACLK. In other words, this oscillator functions as a clock generator. The oscillator 17 supplies the generated internal clock ACLK to the controller part or input/output part 4. The internal clock ACLK is a clock as a reference of the operation of the controller part 3 or input/output part 4.

### 1.2<Controller Part 3>

Next, the controller part will be explained with reference to FIG. 1. The controller part 3 controls the operation of the NAND type flash memory 2 and the input/output part 4. In other words, the controller part has a function of controlling the overall operation of the memory system 1. As shown in the figure, the controller part 3 is provided with an internal register 80 and a state machine 83 for the memory system.

### 1.2.1<Internal Register 80>

The internal register 80 is provided with a register 81 and a command user interface (CUI) 82.

### 1.2.1.1<Register 81>

The register 81 is for setting and storing the operation state of the memory system 1. In other words, the register 81 sets a function operation state in accordance with commands that are issued from an access controller 99. More specifically, the function operation state is set in accordance with a register write command or register read command of the register 81.

In other words, at the time of the load operation, a load command is set in the register 81, at the time of the program operation, the program command is. Here, the register write command or register read command means a write command or read command (write/read) to the register 81 from the access controller 99.

In addition, the register 81 can detect the operation state of the NAND type flash memory 2 by a ready signal and an error signal (RDY/Error in the figure) that are transmitted from the NAND sequencer 15.

### 1.2.1.2<Command User Interface 82>

When a prescribed command is set in the register 81, the command user interface 82 recognizes that a function implementation command has been rendered to the memory system 1, issues an internal command signal (Command), and outputs the command to the state machine 84.

### 1.2.2<State Machine 83 for Memory System>

The state machine 83 for memory system is provided with state machine 84, address/command generating circuit (NAND Add/Command Gen) 85, and address/timing generating circuit (Buffer Add/Timing) 86.

### 1.2.2.1<State Machine 84>

The state machine 84 controls the sequence operation in the memory system 1 based on the internal command signal that is transmitted from the command user interface 82. The functions, which are supported by the state machine 84, are multiple functions such as load, program, and erasure, and the state machine controls the operation of the NAND type flash memory 2 and the input/output part 4 so that these functions are implemented. The state machine 84 controls these parts while synchronizing with the internal clock ACLK that is generated from the oscillator 17.

### 1.2.2.2<Address/Command Generating Circuit 85>

The address/command generating circuit 85 controls the operation of the NAND type flash memory 2 based on the control of the state machine 84. More specifically, this circuit generates addresses or commands such as program, load, and erase (referred to as Command in the figure) and outputs them to the NAND type flash memory 2. The address/command generating circuit 85 outputs these address or commands while synchronizing with the internal clock ACLK that is generated from the oscillator 17.

### 1.2.2.3<Address/Timing Generating Circuit 86>

The address/timing generating circuit 86 controls the operation of the input/output part 4 based on the control of the state machine 84. More specifically, this circuit issues address or commands required for the input/output part 4 and outputs them to the access controller 99 and the ECC controller 72.

### 1.3<Input/Output Part 4>

Next, the input/output part 4 will be explained. The input/output part 4 is provided with ECC part 70, interface part 90, and access controller 99.

In the memory system 1 of this embodiment, the NAND type flash memory 2 functions as a main memory part. Therefore, when the sequencer 15 receives a load command from the address/command generating circuit 85 and reads out data to the outside from the NAND type flash memory 2, the data read out of the memory cell array 10 of the NAND type flash memory 2 is transferred via the page buffer 13 to the interface part 90 of the input/output part 4, so that the data are output to the host appliance not shown in the figure.

On the other hand, when the sequencer 15 receives a program command from the address/command generating circuit 85, it stores data in the NAND type flash memory 2. The data transmitted from the host appliance is transferred to the page buffer 13 via the interface part 90 and written into the memory cell array 10.

Next, the construction of each of the ECC part 70, interface part 90, and access controller 99 will be explained.

### 1.3.1<ECC Part 70>

The ECC part 70 detects and corrects errors of data and generates parity (hereinafter, these operations are sometimes collectively called an ECC processing). In other words, at the time of the load operation, this part detects and corrects errors of data read out of the NAND type flash memory 2. On the other hand, at the beginning of the program operation, this part generates parity of the data to be programmed and stores the generated parity in the memory string MS. The ECC part 70 includes ECC analysis part 71, ECC control part 72, and ECC decoder 73.

### 1.3.1.1<ECC Analysis Part 71>

The ECC analysis part 71 carries out the ECC processing by using data which are held in the page buffer 13. The ECC analysis part 71, for example, uses a 1-bit correction mode using Hamming code. The ECC analysis part 71 generates a syndrome by using the parity which is held in the memory string MS at the time of the load operation and detects errors from the syndrome. When errors are found, the errors are corrected. On the other hand, at the time of the program operation, this analysis part generates parity and stores the parity in the memory string MS.

### 1.3.1.2<ECC Control Part 72>

The ECC control part 72 controls the ECC analysis part 71.

### 1.3.1.3<ECC Decoder 73>

At the time of the load operation, when it is decided by the ECC analysis part 71 that there are errors, the ECC decoder 73 specifies the positions, reads the corresponding data out of the page buffer 13, and corrects the errors. In addition, at the time of the program operation, this decoder transfers the parity generated in the ECC analysis part 71 to the page buffer 13.

### 1.4<Access Controller 99>

The access controller 99 receives a control signal and an address from the interface 92. The access controller 99 controls the controller part 3 and the input/output part 4, so that an operation, which meets the request of the host appliance, may be implemented. More specifically, in response to the request of the host appliance, the access controller 99 controls the NAND type flash memory 2, burst buffer 91, decoder 73, and controller part 3.

For example, in response to the request of the host appliance, the access controller 99 sets the register 81 to an active state and sets a command (Write/Read) in the register 81. In addition, the access controller instructs the page buffer 13 to read data out of the memory cell array 10. Moreover, the access controller transfers an address input from the outside to the decoder 73.

### 1.5<Interface Part 90>

The interface part 90 includes a burst buffer 91 and a user interface (I/F) 92.

The user interface 92 can be connected with the host appliance (user) outside the memory system 1 and is in charge of the input and output of various kinds of signals such as data between the user interface and the host appliance, control signals, and addresses Add. An example of the control signals is chip enable signal/CE for enabling the whole of the memory system 1, address valid signal/AVD for latching an address, clock CLK for burst read and write enable signal/WE for enabling a write operation, output enable signal/OE for enabling the output of data to the outside, etc.

The user interface 92 is connected with the burst buffer 91 by a data input/output bus. The data input/output bus, for example, is 2 bytes. In addition, the user interface 92 transfers the control signals for read request, load request, and program request of data from the host appliance to the access controller 99. Moreover, at a time of a read operation, the user interface outputs data in the burst buffer 91 to the host appliance. Furthermore, at a time of a write operation, the user interface transfers the data, which is transmitted from the host appliance, to the burst buffer 91.

The burst buffer 91 can transfer the data to the page buffer 13 and the control part 4 by a buffer/register data bus. In addition, the burst buffer temporarily holds the data, which are transmitted via the user interface 92 from the host appliance, or the data which are transmitted from the page buffer 13.

### 2.1<Load Sequence>

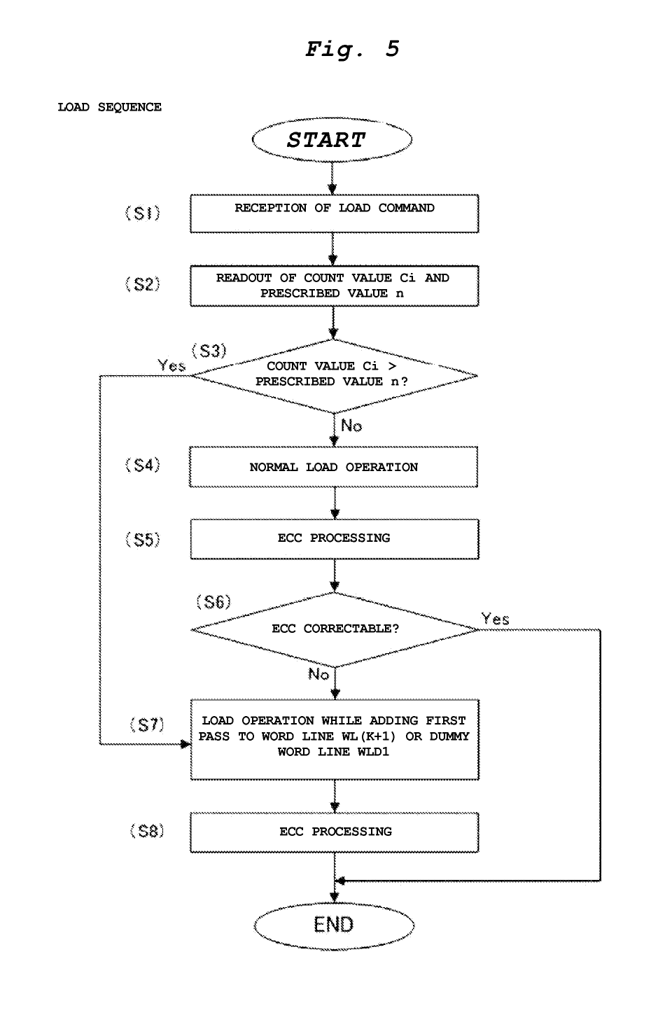

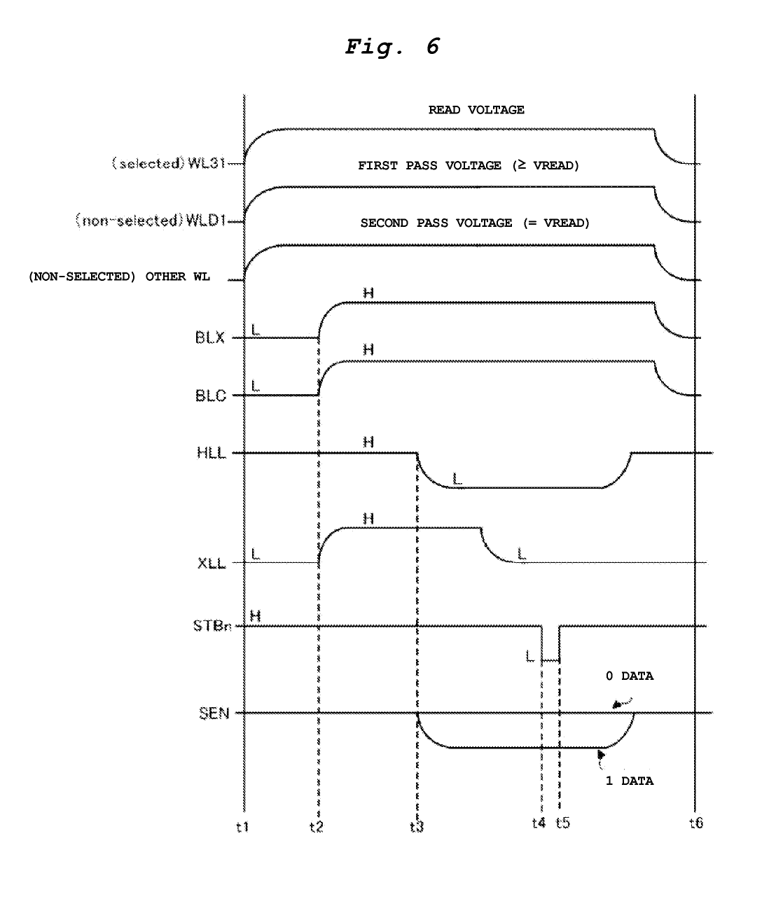

In the load sequence of the memory system of this embodiment, the operation of the sequencer 15 will be explained with reference to a flow chart of FIG. 5 and a timing chart of FIG. 6.

Here, for convenience of explanation, the sense mode of an ABL mode (sense mode for detecting and amplifying a cell current) is explained, however without being limited to it, for example, this embodiment can also be applied to a voltage sense mode. In addition, the case where memory cells MC, which are included in the memory string MS, are 32 pieces will be explained as an example.

As shown in FIG. 5, in step S1, the sequencer 15 receives a load command and an address from the address/command generating circuit 83. The sequencer 15 starts a load operation based on the load command.

Next, in step S2, the sequencer 15 reads out the count value Ci of a selected block BLKi from the counter 15-1 based on the address, and reads out the value n as a prescribed value from the register 15-2.

In step S3, the sequencer 15 compares the count value Ci with the value n and decides whether or not the count value Ci exceeds the value n. If the count value Ci does not exceed the value n (step S3, No), the sequencer 15 carries out a “normal load operation” (step S4).

In other words, the sequencer 15 applies a read voltage to a selected word line WL, electrically connects the sense amplifier 12 and the bit line BL while applying the voltage Vread (second voltage) to the nonselective word lines WL, and detects the potential of the node SEN to implement the load operation. The sequencer 15 transfers the loaded data to the page buffer 13.

In step S5, the sequencer 15 transfers the loaded data to the ECC part 70. Next, in step S6, if the page buffer 13 receives the ECC-processed data via the NAND bus from the ECC part 70, the sequencer 15 decides whether or not the ECC-processed data contain ECC errors (step S6). Here, the ECC errors indicate the case where the ECC-processed data cannot be corrected.

In step S6, if the sequencer 15 decides that the ECC-processed data do not contain ECC errors (step S6, Yes), the ECC-processed data is transferred via a Buffer/Register bus to the interface part 90, so that the load operation is finished.

In step S6, if the sequencer 15 determines that the ECC-processed data contain ECC errors (step S6, No), the sequencer 15 changes the whole setup and reloads data from the memory cell array 10 (step S7).

In step S3, the sequencer 15 compares the count value Ci with the value n, and if the count value Ci exceeds the value n (step S3, Yes), the flow advances to step S7, the whole setup is changed, and the sequencer 15 reloads data from the memory cell array 10 (step S7).

In step S7, when the data of the memory cell MCk is loaded, the sequencer 15 controls the row decoder 11 and the voltage generating circuit 14 so that the first pass voltage is applied to the word line WL(k+1) (first nonselective word line) adjacent to the word line WLk and the second pass voltage is applied to the other nonselective word lines WL (second nonselective word lines).

As shown in FIG. 6, when the data of a memory cell 31 is loaded, the sequencer 15 controls the row decoder 11 and the voltage generating circuit 14 so that the first pass voltage is applied to the dummy word line WLD1 (first nonselective word line) adjacent to the word line WL31 and the second pass voltage is applied to the nonselective word lines WL0-WL30 (second nonselective word lines).

The load sequence of step S7 will be described later in detail.

In step S8, the sequencer 15 transfers the data loaded in step S7 to the ECC part 70 and receives ECC-processed data. The sequencer 15 transfers the ECC-processed data received from the ECC part 70 to the interface part 90 via the buffer/register data bus, so that the load operation is finished.

### 2.2<Operation of Step S7>

Next, the load sequence in step S7 of FIG. 5 will be explained with reference to the flow chart of FIG. 6.

In the following explanation, a load operation that reads data out of the memory cell MC31 will be explained. When data is read out of the memory cell MCk (k=0-30), a similar operation can also be carried out. In this case, the word line WL31 of FIG. 6 is replaced with the word lines WLk, the dummy word line WLD1 is replaced with the word line WL(k+1), and the other word lines WL are replaced with the other word lines WL and dummy word line WLD1.

The word line WL31, which is connected to the memory cell 31 is selected, the first pass voltage is applied to the dummy word line WLD1 (first nonselective word line) adjacent to the word line WL31, and the second pass voltage is applied to the other nonselective word lines WL0-WL30 (second nonselective word lines).

2.2.1<Time t1>

As shown in FIG. 6, at time t1, the row decoder 11 turns on a transfer transistor of selective blocks (not shown in the figure; a transistor in the row decoder 11, one end of a current path is connected to the word lines WL, the other end is connected to the voltage generating circuit 14, and a selective block signal is input into its gate) and connects the voltage generating circuit 14, word lines WL0-WL31, and dummy word line WLD1.

Therefore, the row decoder 11 transfers the read voltage to the selected word line WL31. In addition, the row decoder 11 transfer the first pass voltage to the dummy word line WLD1 and transfers the second pass voltage to the other nonselective word lines WL0-WL30.

Here, the read voltage will be briefly explained. For example, when the memory cells MC are quaternary (2 bits) data, the data are decided by using a voltage between each distribution (for example, a voltage between E distribution and A distribution) as the read voltage to specify whether or not the threshold voltage of the memory cells MC is in a range of E distribution, A direction, B distribution, and C distribution.

“H” level is applied to the gate of the transistor Tr3 in the sense amplifier 12 to turn on the transistor Tr3. In addition, “H” level is applied to the gate of the transistor Tr6 in the sense amplifier 12 to turn off the transistor Tr6.

2.2.2<Time t2>

Next, at time t2, “H” level is applied to the gates of the transistors Tr1, Tr2, and Tr4 in the sense amplifier 12 to turn on the transistors Tr1, Tr2, and Tr4. As a result, the potential of the bit lines BL is charged via the transistors Tr2 and Tr1. In addition, the potential of the node SEN is also charged to “H” level via the transistor Tr3.

2.2.3<Time t3>

At time t3, “L” level is applied to the gate of the transistor Tr3 in the sense amplifier 12 to turn off the transistor Tr3, cutting off the transistor. As a result, in case the memory string MS is conductive, the potential of the node SEN is discharged via the transistor Tr4 and the bit lines BL. The potential of the node SEN is then turned to “L” level.

On the other hand, in case the memory string MS is nonconductive, the potential of the node SEN is not discharged but holds the “H” level.

2.2.4<Time t4-t5>

At time t4-t5, “L” level is applied to the gate of the transistor Tr6 to turn on the transistor Tr6, so that the data held at the node SEN are held in the latch circuit (SDC) in the sense amplifier 12. Specifically, in case the node SEN is at “L” level, the transistor Tr5 is turned on, and the “L” level is held in the latch circuit (SDC).

On the other hand, in case the node SEN is at “H” level, the transistor Tr5 is turned off, and the “H” level is held in the latch circuit (SDC). Here, an initial state can be initialized by turning on the transistor Tr7. At the initial stage, the latch circuit (SDC) has “H” level.

At time t5, after the data is read out to the latch circuit (SDC), the data is transferred to the page buffer 13, so that the load operation is completed.

3.1<Effects of this Embodiment>

According to the memory system of this embodiment, the following effects (1) and (2) can be obtained.

(1) Incorrect readout of data can be Reduced.

Usually, in case data are written into one block, the data is written one page by one page in elevating order of memory cell MC0, memory cell MC1, . . . , memory cell MC31. Therefore, when the data is written into the memory cells MC0, the data is not written into the remaining memory cells MC1-MC31, and the memory cells MC1-MC31 are in an erasure state. On the other hand, when the data is written into the memory cells MC31, the data has already been written into the remaining memory cells MC0-MC30. In other words, when the data is written into the memory cells MC0, the load capacitance is smaller than the load capacitance when the data is written into the memory cells MC31. As a result, even if “10” data is written into both one page of the memory cells MC0 and one page of the memory cells MC31, the threshold distribution of the memory cells MC31 in one page is relatively lower than the threshold distribution of the memory cells MC0 in one page for example. The larger a difference between the threshold distribution of the memory cells MC31 and the threshold distribution of the memory cells MC0 is, the wider threshold distribution of “10” data is.

Therefore we need to make the difference smaller in order to narrow the width of threshold distribution of “10” data.

As Comparative Example 1, the case where the dummy memory cells MD are not included in the memory strings MS and data is read out by a DLA (Direct Look Ahead) technique will be reviewed.

In Comparative Example 1, when data of a memory cells MCk (k=0-30) is read out, a desired read voltage is applied to a word line WLk while a desired voltage based on the DLA technique is applied to a word line WL(k+1) adjacent to the word line WLk. In that case, the threshold voltage of the memory cell MCk can be shifted to a negative side because of canceling a coupling received from the adjacent memory cell MC(k+1).

However, the wiring adjacent to the word line WL31 is the selective gate line SGD, and when data of the memory cell MC31 is read out, the DLA technique cannot be applied.

The inventors obtained the following knowledge through an experiment. When data of the memory cells MC0-MC30 are read out, if the data are read out using the DLA technique, the threshold distribution of the memory cells MC0-MC30 can be shifted to lower side. If the threshold distribution of the memory cells MC0-MC30 is shifted too much, it is possible that the threshold distribution of the memory cells MC31 becomes higher than the threshold distribution of the memory cells MC0-MC30. In other word, the difference between the threshold distribution of the memory cells MC31 and the threshold distribution of the memory cells MC0 remains large.

Furthermore the threshold distribution of the memory cells MC0-MC30 can be narrow by using the DLA technique. Therefore it is possible that the difference between the threshold distribution of the memory cells MC31 and the threshold distribution of the memory cells MC0 may widen. Therefore the data is sometimes incorrectly read out.

In Comparative Example 1, sometimes, incorrect readout of the data still occurs, however in this memory system of this embodiment, when data of the memory cell MC31 is read out, the first pass voltage (>voltage Vread) is applied to the dummy word line WLD1 adjacent to the word line WL31. Therefore, in the memory system of this embodiment, the threshold distribution of the memory cell MC31 can also be apparently shifted to the negative side similarly to the memory cells MC0-MC31, so that incorrect readout of the data can be reduced, compared with Comparative Example 1.

(2) While suppressing the increase of the read operation time, incorrect readout of data can be reduced.

In Comparative Example 2, the case where the sequencer 15 does not compare the count value Ci with the value n but applies the first pass voltage to the dummy word line WLD1 (first nonselective word line) adjacent to the word line WL31 and applies the second pass voltage to the other nonselective word lines WL0-WL30 (second nonselective word lines) each time the word line WL31, which is connected to the memory cell 31, is selected will be reviewed.

In Comparative Example 2, each time the word line WL31 that is connected to the memory cell 31 is selected, it is necessary to charge the dummy word line WLD1, increasing the readout time.

However, in the memory system of this embodiment, the sequencer 15 compares the count value Ci with the value n and decides whether or not the count value Ci exceeds the value n. If the count value Ci does not exceed the value n (step S3, No), the sequencer 15 carries out a “normal load operation” (step S4). In case the reliability of the memory cells is not changed from the reliability of an initial state, when its value n is assumed as a prescribed value, if an erasure operation and. a program operation are repeated less than n times. The reliability of the memory cells are not much changed from the initial state, and ECC errors due to the ECC processing are also few. As a result, in this embodiment, the operation of step S7 can be reduced compared with Comparative Example 2. Therefore, in this embodiment, the increase of the readout time can be suppressed, compared with Comparative Example 2.

### Modified Example 1

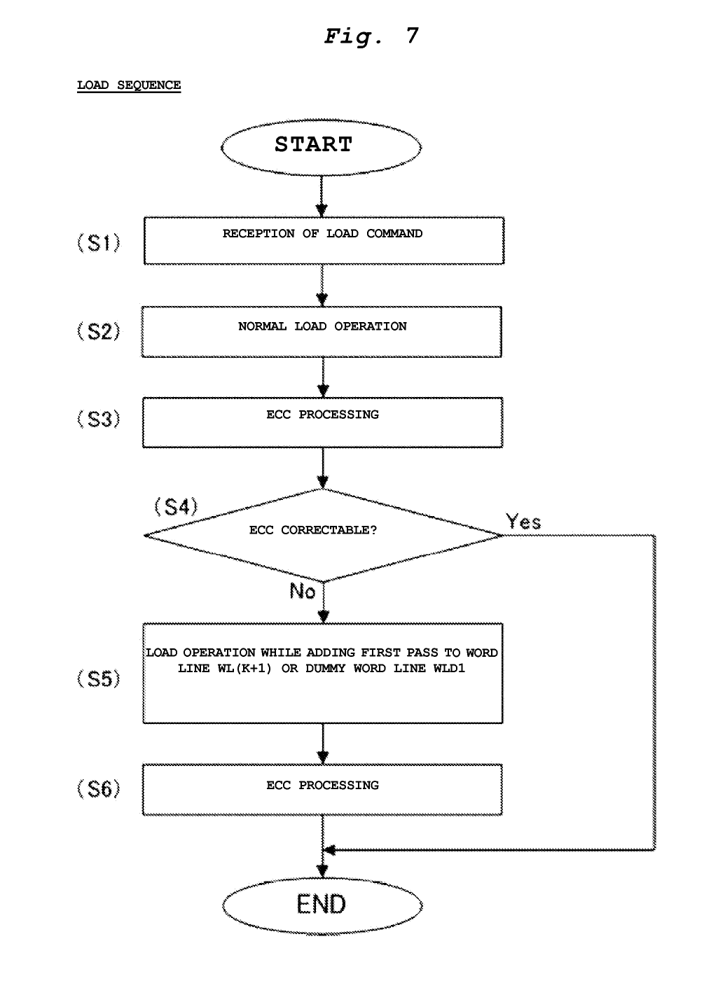

Next, the memory system of Modified Example 1 of this embodiment will be explained with reference to a flow chart of FIG. 7. The load sequence of the sequencer 15 of the memory system of Modified Example 1 is different from that of the memory system of the first embodiment, and since the other operations and constitutions of the memory system are similar, their detailed explanation is omitted.

Next, the load sequence of the sequencer 15 will be explained with reference to FIG. 7.

As shown in FIG. 7, in step S1, the sequencer 15 receives a load command and an address from the address from the address/command generating circuit 83. The sequencer 15 starts a load operation based on the load command.

Next, in step S2, the sequencer 15 carries out a “normal load operation” (step S4). In other words, the sequencer 15 applies a read voltage to a selected word line WL, electrically connects the sense amplifier 12 and the bit line BL while applying the voltage Vread (second pass voltage) to the nonselective word lines WL, and detects the potential of the node SEN to implement the load operation. The sequencer 15 transfers the loaded data to the page buffer 13.

In step S3, the sequencer 15 transfers the loaded data to the ECC part 70. Next, in step S4, if the page buffer 13 receives the ECC-processed data via the NAND bus from the ECC part 70, the sequencer 15 decides whether or not the ECC-processed data are ECC errors. Here, the ECC errors indicate the case where the data loaded by the ECC processing cannot be corrected.

In step S4, if the sequencer 15 decides that the ECC-processed data are not the ECC errors (step S4, Yes), the ECC-processed data are transferred via the buffer/register bus to the interface part 90, so that the load operation is finished.

In step S4, if the sequencer 15 decides that the ECC-processed data are the ECC errors (step S4, No), the sequencer 15 changes the whole setup and reloads data from the memory cell array 10 (step S5).

In step S5, when the data of the memory cell MCk are loaded, the sequencer 15 controls the row decoder 11 and the voltage generating circuit 14 so that the first pass voltage is applied to the word line WL(k+1) (first nonselective word line) adjacent to the word line WLk and the second pass voltage is applied to the other nonselective word lines WL (second nonselective word lines).

Similarly to FIG. 6, when the data of the memory cell 31 is loaded, the sequencer 15 controls the row decoder 11 and the voltage generating circuit 14 so that the first pass voltage is applied to the dummy word line WLD1 (first nonselective word line) adjacent to the word line WL31 and the second pass voltage is applied to the other nonselective word lines WL0-WL30 (second nonselective word lines).

In step S6, the sequencer 15 transfers the data loaded in step S5 to the ECC part 70 and receives ECC-processed data. The sequencer 15 transfers the ECC-processed data received from the ECC part 70 to the interface part 90 via the buffer/register data bus, so that the load operation is finished.

3. <Effects of Modified Example 1 of this Embodiment>

According to the memory system of Modified Example 1 of this embodiment, the following effect (1) can be obtained.

(1) Incorrect Readout of Data can be Reduced.

Modified Example 1 exerts an effect similar to the effect of the first embodiment.

### Modified Example 2

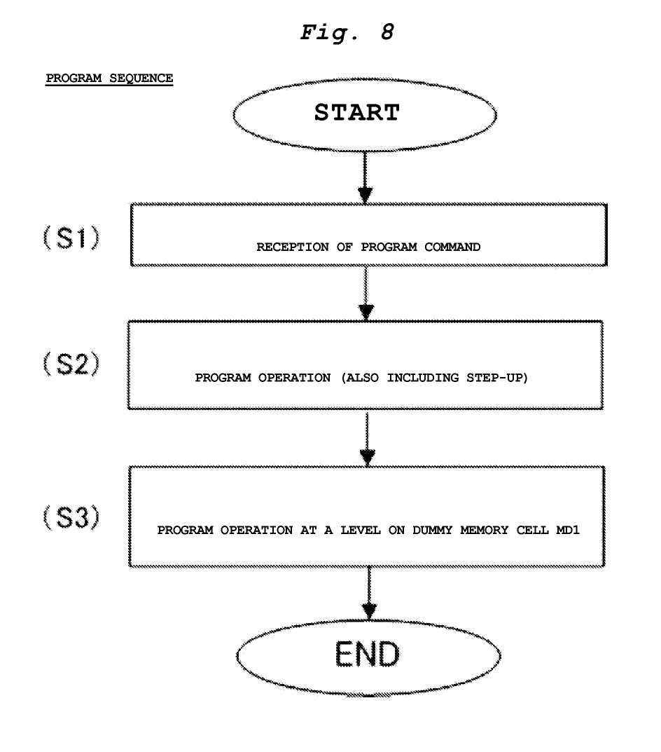

Next, the memory system of Modified Example 2 of this embodiment will be explained with reference to a flow chart of FIG. 8. The program sequence of the sequencer 15 of the memory system of Modified Example 2 is different from that of the memory system of the first embodiment, and since the other operations and constitutions of the memory system are similar, their detailed explanation is omitted.

### <Program Sequence>

Next, the program operation of the sequencer 15 will be explained by an example in which data of one block are programmed.

As shown in FIG. 8, in step S1, the sequencer 15 receives a program command and address from the address/command generating circuit 83. The sequencer 15 starts a program operation based on the program command.

In step S2, the sequencer 15 controls the sense amplifier 12, page buffer 13, row decoder 11, and voltage generating circuit 14 so that data (also including parity of ECC) held in the page buffer 13 are programmed and verified.

The page buffer 13 transfers this data to the sense amplifier 12, and the sense amplifier 12 controls the potential of each bit line BL based on “0” and “1” of the data.

The voltage Vpgm (for example, 20 V) is applied to the word line WL, which is selected by the row decoder 11, and the voltage Vpass (pass voltage, for example, 10 V) is applied to the nonselective word lines WL.

As a result, the data is programmed at one page unit in the memory cells MC. After the program operation, a verification operation is carried out to verify the data, and the voltage Vpgm is stepped up in an ISPP mode until the verification pass to implement the program operation.

For example, in case data is programmed in memory cells of one block, the data is programmed at a page unit in the order of the memory cells MC1, MC2, . . . , and MC31.

In step S3, after programming the data in one page of the memory cell MC31, “01” data (data at A level) are programmed in one page of the dummy memory cell MD1. The program and verification operations are similar to step S2, however “01” data is automatically programmed regardless of the data held in the page buffer 13.

Here, in Modified Example 2, “01” data is programmed in the dummy memory cell MD1, however without being limited to this case, for example, “10” and “00” data may also be adopted.

### <Load Sequence>

The load sequence of Modified Example 2 will be briefly explained. In the first embodiment, when the word line WL31 that is connected to the memory cell 31 is selected, the first pass voltage is applied to the dummy word line WLD1 (first nonselective word line) adjacent to the word line WL31, and the second pass voltage is applied to the other nonselective word lines WL0-WL30 (second nonselective word lines).

In Modified Example 2, as the first pass voltage, any voltage at which the dummy memory cell MD1 at A level passes may be adopted, and the voltage may also be smaller than the second pass voltage.

<Effects of Modified Example 2 of this Embodiment>

According to the memory system of Modified Example 2 of this embodiment, the following effect (1) can be obtained.

(1) Incorrect readout of data can be reduced.

Modified Example 2 exerts an effect similar to the effect of the first embodiment.

(2) While suppressing the increase of the read operation time, incorrect readout of data can be reduced.

Modified Example 2 exerts an effect similar to the effect of the first embodiment.

(3) The voltage stress, which is applied to the memory cells MC and the dummy memory cells MD, can be reduced, improving the reliability.

In the first embodiment, the first pass voltage is applied to the dummy word line WLD1 adjacent to the word line WL31. The first pass voltage, for example, a voltage exceeding 20 V, and an excessive voltage stress is applied to the dummy memory cells MD. In addition, the excessive voltage stress is also applied to the memory cells MC by coupling, so that the reliability of the memory cells MC and the dummy memory cells MD is sometimes lowered.

However, in Modified Example 2, as the first pass voltage, any voltage at which the dummy memory cell MD1 at A level passes may be adopted, and the voltage may also be smaller than the second pass voltage. For this reason, in Modified Example 2, the voltage stress, which is applied to the memory cells MC and the dummy memory cells MD, can be reduced, thus being able to improve the voltage stress, compared with the first embodiment.

### Second Embodiment

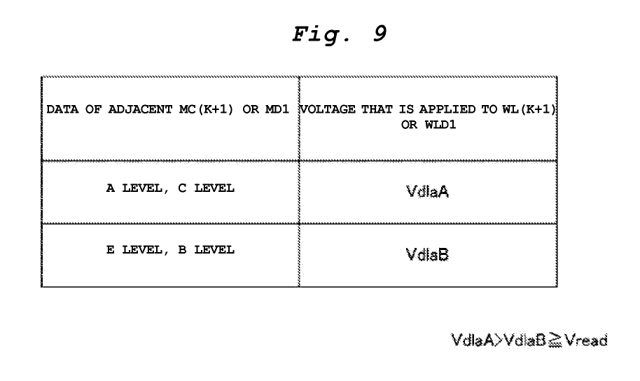

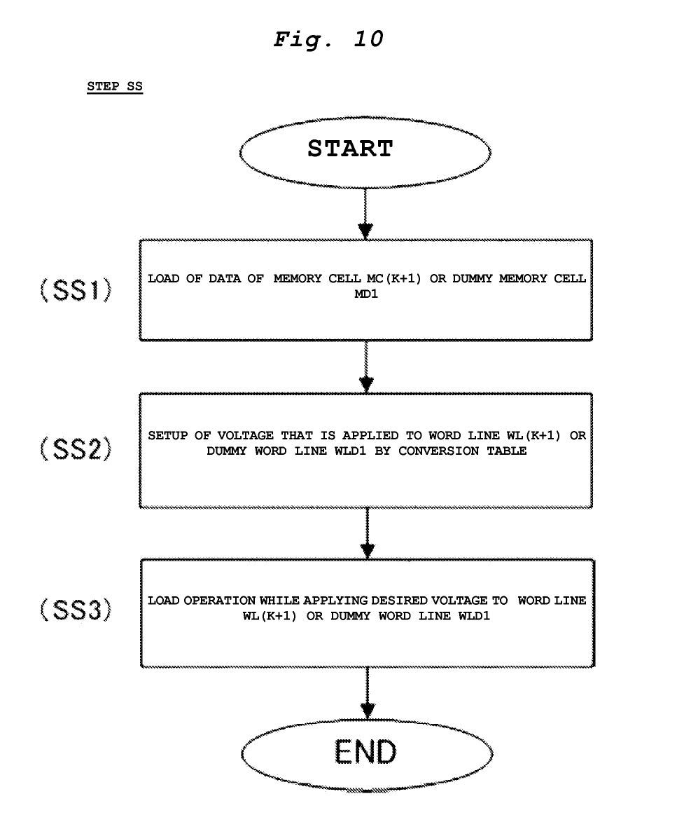

Next, the memory system of the second embodiment will be explained with reference to a conversion table of FIG. 9 and a flow chart of FIG. 10. The load operation of the sequencer 15 of the memory system of the second embodiment is different from that of the memory system of the first embodiment, and the other operations are similar to those of the memory system of the first embodiment. The memory system of the second embodiment is different from the first embodiment and Modified Example 1 in that the sequencer 15 further has a conversion table, and since the other constitutions are similar to those of the first embodiment and Modified Example 1, their detailed explanation is omitted.

### <Sequencer 15>

Next, the construction of the sequencer 15 will be explained with reference to FIG. 9. The sequencer 15 further has the conversion table of FIG. 9 in the register 15-2. The conversion table of FIG. 9 is a conversion table of the case where memory cells can hold quaternary (2 bits) data. In addition, this conversion table is a conversion table of the case where quaternary data are written via an LM distribution by a programming method of data. Here, the LM mode will be described later.

In the conversion table, when a memory cell MCk is selected, data held in its adjacent memory cell MC(k+1) or dummy memory cell MD1 and voltages, which are applied to the word line WL(k+1) or dummy word line WLD1, are made to correspond to each other.

In the conversion table of FIG. 9, when the data held in the adjacent memory cell MC(k+1) or dummy memory cell MD1 are at A level (threshold voltage in a range of A distribution) and C level (threshold voltage in a range of C distribution), a voltage VdlaA is applied to the word line WL(k+1) or dummy word line WLD1.

When the data held in the adjacent memory cell MC(k+1) or dummy memory cell MD1 are at E level (threshold voltage in a range of E distribution) and B level (threshold voltage in a range of B distribution), a voltage VdlaB is applied to the word line WL(k+1) or dummy word line WLD1.

Here, the voltage relation of the voltages VdlaA, VdlaB, and Vread (second pass voltage) satisfies (expression 1).

VdlaA>VdlaB≧Vread(second pass voltage) (expression 1)

The sequencer 15 carries out a load sequence by the conversion table. Next, details of the load sequence will be explained with reference to FIG. 10. The load sequence of this embodiment is different from only the step S7 of FIG. 5 of the first embodiment and only the step S5 of FIG. 7 of Modified Example 1, and the other operations are similar. Next, step SS, which replaces the step S7 of FIG. 5 of the first embodiment and the step S5 of FIG. 7 of Modified Example 1, will be explained.

As shown in FIG. 10, step SS includes three steps.

First, in step SS1, when the memory cell MC to be read out is the memory cell MCk (k=0-30), the sequencer 15 loads data of the memory cell MC(k+1). When the memory cell MC to be loaded is the memory cell MC31, the sequencer 15 loads data of the dummy memory cell MD1. The sequencer 15 transfers the loaded data to the page buffer 13 and the page buffer 13 holds the loaded data.

In step SS2, the sequencer 15 sets a voltage, which is applied to the word line WL(k+1) or dummy word line WLD1 adjacent to the memory cell MCk to be read out, based on the loaded data and the conversion table of the register 15-2.

Specifically, when the data of the memory cell MC(k+1) or the data of the dummy memory cell MD1 are at A level or C level, the sequencer 15 controls the row decoder 11 and the voltage generating circuit 14 so that the corresponding voltage VdlaA is applied to the word line WL(k+1) or dummy word line WLD1 based on the conversion table.

On the other hand, when the data of the memory cell MC(k+1) or the data of the dummy memory cell MD1 are at E level or B level, the sequencer 15 controls the row decoder 11 and the voltage generating circuit 14 so that the corresponding voltage VdlaB is applied to the word line WL(k+1) or dummy word line WLD1 based on the conversion table.

Next, in step SS3, the memory cell MCk to be read out is read out while the voltage VdlaA or VdlaB is applied to the word line WL(k+1) or dummy word line WLD1.

### Effects of this Embodiment

According to the memory system of this embodiment, the following effects (1)-(3) can be obtained.

(1) Incorrect readout of data can be reduced.

An effect similar to the effect of the first embodiment is exerted. In the memory system of this embodiment, when data of the memory cell MC31 is read out, the first pass voltage (>voltage Vread) is applied to the dummy word line WLD1 sunk in the word line WL31. For this reason, in the memory system of this embodiment, the threshold distribution of the memory cell MC31 can also be apparently shifted to a negative side similar to the memory cells MC0-MC31, so that incorrect readout of the data can be reduced, compared with Comparative Example 1.

(2) While suppressing the increase of the read operation time, incorrect readout of data can be reduced.

An effect similar to the effect of the first embodiment is exerted. In other words, in the sequencer 15 of the memory system of this embodiment, if the count value Ci does not exceed the value n (step S3, No), the sequencer 15 carries out a “normal load operation” (step S4). In case an erasure operation and a write operation are repeated n times or less, the reliability of the memory cells are not much changed from the initial state, and ECC errors due to the ECC processing are also few. Therefore, in this embodiment, the increase of the readout time can be suppressed, compared with Comparative Example 2.

(3) The threshold distribution of data can be further narrowed.

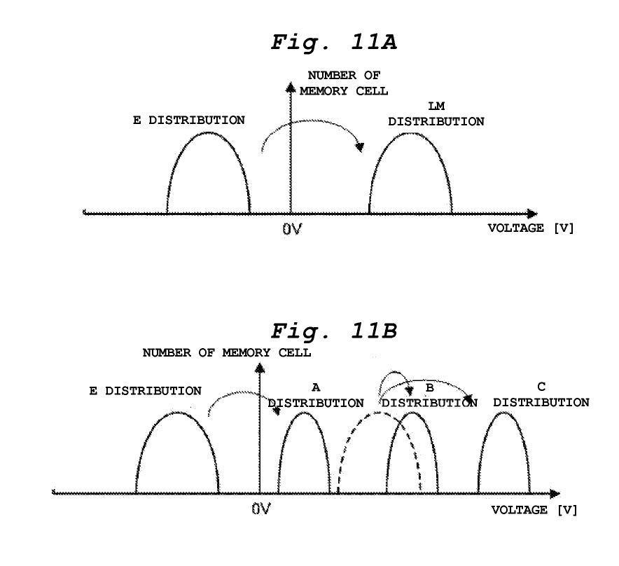

In case data are written into memory cells that can hold 2-bit data, for example, a method (LM mode) for writing the data via an LM distribution as shown in FIGS. 11A and 11B is known.

First, a program operation of lower bit data is carried out (see FIG. 11A). The sequencer 15 controls the row decoder 11 and the voltage generating circuit 14 so that the threshold distribution holds E distribution, when the lower bit data are “1”, and the threshold distribution is LM distribution as an intermediate distribution when the lower bit data are “0”

Next, a program operation of upper bit data is carried out (see FIG. 11B). If the lower bit data are “1,” the sequencer 15 controls the row decoder 11 and the voltage generating circuit 14 so that the threshold distribution holds E distribution, when the threshold voltage is E distribution, and the threshold distribution holds B distribution when the threshold distribution is LM distribution. If the upper bit data are “0” the sequencer controls the row decoder and the voltage generating circuit so that the threshold distribution is A distribution, when the threshold distribution is E distribution, and the threshold distribution is C distribution when the threshold distribution is LM distribution.

As a result, E distribution, A distribution, B distribution, and C distribution correspond to “11”, “01”, “10”, “00,” respectively.

When the data of the memory cell MC(k+1) or dummy memory cell MD1 adjacent to the memory cell MCk to be loaded are at A level or C level, the adjacency effect is high, compared with the case where the data are at E level or B level, the threshold distribution of the memory cell MCk to be loaded is sometimes shifted. Here, since the data of the memory cells MC0-MC(k−1) have already been programmed, the data have no influence on the threshold distribution of the memory cell MCk to be read out.

When the data of the memory cell MCk is loaded, an apparent amount of the threshold distribution to a negative side can be regulated by changing the kind of voltage higher than the voltage Vread in the word line WL(k+1) or dummy word line WLD1, thus being able to narrow the threshold distribution of the entire memory cell MCk.

### Modified Example 3

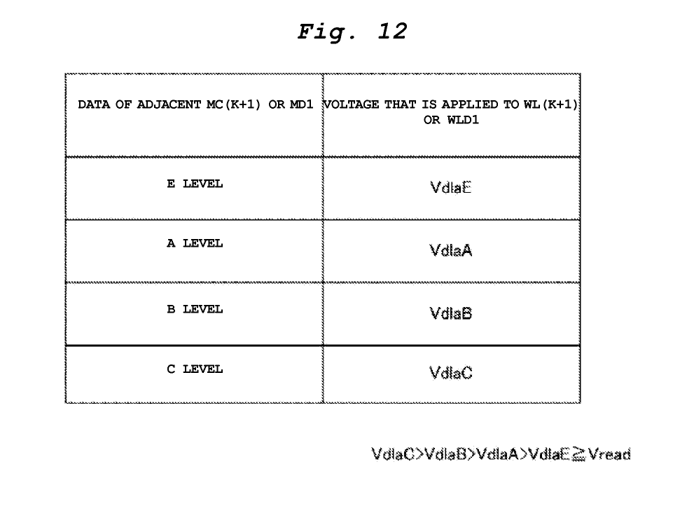

Next, the memory system of Modified Example 3 of the second embodiment will be explained using the conversion table of FIG. 12. In the memory system of Modified Example 3, the programming method of data is different from that of the second embodiment.

The programming method of Modified Example 3 is a mode that directly writes A distribution, B distribution, and C distribution because the threshold distribution is E distribution in an erasure state, without interposing the LM distribution of the second embodiment.

### <Conversion Table>

In the conversion table of Modified Example 3, as shown in FIG. 12, when the data held in its adjacent memory cell MC(k+1) or dummy memory cell MD1 is at A level, a voltage VdlaA is applied to the word line WL(k+1) or dummy word line WLD1. When the data held in the adjacent memory cell MC(k+1) or dummy memory cell MD1 is at B level, a voltage VdlaB is applied to the word line WL(k+1) or dummy word line WLD1. When the data held in the adjacent memory cell MC(k+1) or dummy memory cell MD1 is at C level, a voltage VdlaC is applied to the word line WL(k+1) or dummy word line WLD1. When the data held in the adjacent memory cell MC(k+1) or dummy memory cell MD1 is at E level (erasure state), a voltage VdlaE is applied to the word line WL(k+1) or dummy word line WLD1.

Here, the voltage relation of the voltages VdlaE, VdlaA, VdlaB, VdlaC, and Vread (second pass voltage) satisfies (expression 2).

VdlaC>VdlaB>VdlaA≧VdlaEVread(second pass voltage) (expression 2)

The sequencer 15 carries out a load sequence by the conversion table. Since the load sequence of Modified Example 3 is similar to the load sequence of the second embodiment, its detailed explanation is omitted. Data of the adjacent memory cell MC(k+1) or dummy memory cell MD1 is loaded, the corresponding voltage VdlaE-VdlaC is set, and data of the selected memory cell MCk is loaded while the voltage corresponding to the word line WL(k+1) or dummy word line WLD1 is applied.

### <Effects of Modified Example 3>

According to the memory system of Modified Example 3, the following effects (1)-(3) can be obtained.

(1) Incorrect readout of data can be reduced.

An effect similar to the effect of the first embodiment is exerted.

(2) While suppressing the increase of the read operation time, incorrect readout of data can be reduced.

An effect similar to the effect of the first embodiment is exerted.

(3) The threshold distribution of data can be further narrowed.

In case data is written into memory cells that can hold 2-bit data, the program mode of Modified Example 3 is a mode that directly writes A distribution, B distribution, and C distribution because the threshold distribution is E distribution in an erasure state, without interposing the LM distribution of the second embodiment.

Therefore, when the data of the memory cell MC(k+1) or dummy memory cell MD1 adjacent to the memory cell MCk to be read out are at A level, the amount of shift of the threshold distribution is large, compared with the case where the data is at E level, and when the data of the memory cell MC(k+1) or dummy memory cell MD1 adjacent to the memory cell MCk are at B level, the amount of shift of the threshold distribution is large, compared with the case where the data are at A level. When the data of the memory cell MC(k+1) or dummy memory cell MD1 adjacent to the memory cell MCk are at C level, the amount of shift of the threshold distribution is large, compared with the case where the data is at B level,

In the memory system of Modified Example 2, when the data of the memory cell MCk is loaded, an apparent amount of shift of the threshold distribution to a negative side can be regulated based on the data written in the memory cell MC(k+1) or dummy memory cell MD1 by changing the kind of voltage higher than the voltage Vread in the word line WL(k+1) or dummy word line WLD1, thus being able to narrow the threshold distribution of the entire memory cell MCk.

### Modified Example 4

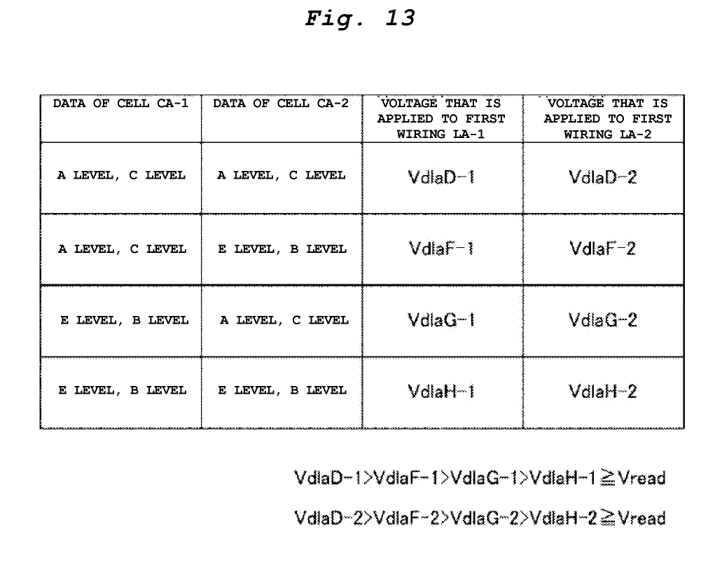

Next, the memory system of Modified Example 4 of this embodiment will be explained using the conversion table of FIG. 13. In the memory system of Modified Example 4, the conversion table and the load sequence of the sequencer 15 are different from those of the second embodiment.

In the second embodiment, one memory string MS has two dummy memory cells MD, however in Modified Example 4, one memory string MS has 2j pieces (j represents a natural number) of dummy memory cells MD. Between the memory cell MC31 and the bit lines BL, j pieces of dummy memory cells MD are installed, whose symbols are assumed as dummy memory cells MD(j+1)-MD2j.

In the load sequence of Modified Example 4, when data of the memory cell 31 are loaded, the adjacency effect is calculated based on the data pattern up to the dummy memory cells MD(j+1)-MD2j, and the data of the memory cell MC31 is loaded while the corresponding voltage in the conversion table is applied to the dummy word lines WLD(j+1)-WLD2j.

Similarly, when data of the memory cell MC0 is loaded, the adjacency effect is calculated based on the data pattern up to the dummy memory cells MC1-MCj, and the data of the memory cell MC0 are loaded while the corresponding voltage in the conversion table is applied to the dummy word lines WL1-WLj.

The word lines WL and the dummy word lines WLD are processed as first wirings in the same column, and the voltage, which is applied to j pieces of first wirings adjacent to a selected memory cell MC, is determined based on the conversion table.

### <Conversion Table>

The conversion table of FIG. 13 is a conversion table when j=2.

The memory cell adjacent to a selected memory cell MC is assumed as cell CA-1, and the cell adjacent to the cell CA-1 is assumed as cell CA-2. The cells CA-1 and CA-2 are any of the memory cells MC and the dummy memory cells MD.

The first wiring, which is connected to the cell CA-1, is assumed as first wiring LA-1, and the first wiring, which is connected to the cell CA-2, is assumed as first wiring LA-2.

In the conversion table of FIG. 13, when data of the cell CA-1 is at A level or C level and data of the cell CA-2 is at A level or C level, a voltage VdlaD-1 is applied to the first wiring LA-1, and a voltage VdlaD-2 is applied to the first wiring LA-2. When data of the cell CA-1 is at A level or C level and data of the cell CA-2 is at E level or B level, a voltage VdlaF-1 is applied to the first wiring LA-1, and a voltage VdlaF-2 is applied to the first wiring LA-2. When data of the cell CA-1 is at E level or B level and data of the cell CA-2 is at A level or C level, a voltage VdlaG-1 is applied to the first wiring LA-1, and a voltage VdlaG-2 is applied to the first wiring LA-2. When data of the cell CA-1 is at E level or B level and data of the cell CA-2 is at E level or B level, a voltage VdlaH-1 is applied to the first wiring LA-1, and a voltage VdlaH-2 is applied to the first wiring LA-2.

Here, the voltage relation of the voltages VdlaD-1, VdlaF-1, VdlaG-1, VdlaH-1, and Vread satisfies (expression 3).

VdlaD-1>VdlaF-1>VdlaG-1>VdlaH-1≧Vread (expression 3)

Here, the voltage relation of the voltages VdlaD-2, VdlaF-2, VdlaG-2, VdlaH-2, and Vread satisfies (expression 4).

VdlaD-2>VdlaF-2>VdlaG-2>VdlaH-2≧Vread (expression 4)

The voltage VdlaD-1 is equal to VdlaD-2, the voltage VdlaF-1 is equal to the voltage VdlaF-2, the voltage VdlaG-1 is equal to the voltage VdlaG-2, and the voltage VdlaH-1 is equal to the voltage VdlaH-2. Without being limited to this case, if the voltage relation of the voltage VdlaD-1 to VdlaH-1 and VdlaD-2 to VdlaH-2 meets the expressions 3 and 4, any pattern can be designed and changed. For example, the voltage VdlaD-1 may be higher than VdlaD-2, the voltage VdlaF-1 may be higher than the voltage VdlaF-2, the voltage VdlaG-1 may be higher than the voltage VdlaG-2, and the voltage VdlaH-1 may be higher than the voltage VdlaH-2.

The sequencer 15 carries out a load sequence by the conversion table. Since the load sequence of Modified Example 4 is similar to the load sequence of the second embodiment, its detailed explanation is omitted. Data of the adjacent memory cells CA-1 and CA-2 are loaded, the corresponding voltage VdlaD-1 to VdlaH-1 and VdlaD-2 to VdalH-2 are set, and data of a selected memory cell MC is loaded while the voltages corresponding to the first wirings LA-1 and LA-2 are applied.

### <Effects of Modified Example 4>

According to the memory system of Modified Example 4, the following effects (1)-(3) can be obtained.

(1) Incorrect readout of data can be reduced.

An effect similar to the effect of the first embodiment is exerted.

(2) While suppressing the increase of the read operation time, incorrect readout of data can be reduced.

An effect similar to the effect of the first embodiment is exerted.

(3) The threshold distribution of data can be further narrowed, and the amount of shift of the threshold distribution can also be more precisely regulated.

An effect similar to that of Modified Example 3 is exerted. Especially in a load operation of Modified Example 4, when data of the memory cell 31 is loaded, the adjacency effect is calculated based on a data pattern up to the dummy cells MD(j+1)-MD2j, and the data of the memory cell MC31 is loaded while the corresponding voltages in the conversion table are applied to the dummy word lines WLD(j+1)-WLD2j. In addition to the adjacency effect of j pieces of cells adjacent to a selected memory cell, the voltage of the first wiring is adjusted.

Therefore, in Modified Example 4, the threshold distribution of data can be further narrowed, and the amount of shift of the threshold distribution can also be more precisely regulated.

Here, the present disclosure is not limited to the aforementioned embodiments but can be variously modified in the range where its essence is not deviated at its application stage. In all of the aforementioned embodiments and modified examples, the sequencer 15 has the counter 15-1 or register 15-2 and controls a load sequence. However, without being limited to this case, for example, the state machine 83 for memory system may have a counter or register, and the load sequence may be implemented by controlling the sequencer 15. In other words, the load sequence may be controlled by the controller part 3.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system, comprising:
nonvolatile memory cells each configured to store more than one bit of data;
dummy memory cells; and
a controller configured to control application of voltages to gates of the nonvolatile memory cells and the dummy memory cells, such that during an operation to read data from a group of the nonvolatile memory cells that are adjacent to the dummy memory cells, a read voltage is applied to the gates of the nonvolatile memory cells in the group while a first voltage is applied to gates of the dummy memory cells and a second voltage is applied to the other groups of the nonvolatile memory cells, the first voltage being higher than the second voltage.

2. The memory system according to claim 1, wherein
during the operation to read data from the group of the nonvolatile memory cells that are adjacent to the dummy memory cells, the read voltage is applied to the gates of the nonvolatile memory cells in the group while the first voltage is applied to gates of the dummy memory cells and the second voltage is applied to the other groups of the nonvolatile memory cells, in response to determining that the operation to read data from the group of the nonvolatile memory cells results in an error that is not correctable by error correction coding.

3. The memory system according to claim 1, wherein
during the operation to read data from the group of the nonvolatile memory cells that are adjacent to the dummy memory cells, the read voltage is applied to the gates of the nonvolatile memory cells in the group while the first voltage is applied to gates of the dummy memory cells and the second voltage is applied to the other groups of the nonvolatile memory cells, in response to determining that the group of the nonvolatile memory cells has undergone erase and program operations a number of times that exceed a predetermined number.

4. The memory system according to claim 1, wherein
during an operation to read data from another group of the nonvolatile memory cells that are not adjacent to the group of the nonvolatile memory cells, the read voltage is applied to the gates of the nonvolatile memory cells in the another group while the second voltage is applied to the other groups of the nonvolatile memory cells.

5. The memory system according to claim 4, wherein
the first voltage is applied to gates of the nonvolatile memory cells that are adjacent to the nonvolatile memory cells in the another group on the side of the dummy memory cells and is not applied to gates of the nonvolatile memory cells that are adjacent to the nonvolatile memory cells in the another group on the side opposite the dummy memory cells.

6. The memory system according to claim 1, wherein
if data stored in the dummy memory cells are first data, the read voltage is applied to the gates of the nonvolatile memory cells in the group while applying a third voltage that is higher than the second voltage to the gates of the dummy memory cells, and
if data stored in the dummy memory cells are second data, the read voltage is applied to the gates of the nonvolatile memory cells in the group while applying a fourth voltage that is higher than the third voltage to the gates of the dummy memory cells.

7. The memory system according claim 6, wherein
the controller maintains a table that associates voltages to be applied to the gates of the dummy memory cells with data stored therein.

8. A memory system, comprising:
multiple memory strings each including a plurality of nonvolatile memory cells connected serially between first and second selection transistors, each memory string including a dummy memory cell adjacent to the first selection transistor and each nonvolatile memory cell configured to store more than one bit of data;
a plurality of word lines, each word line connected to a gate of a different memory cell in each of the memory strings, the word lines including a dummy word line connected to a gate of the dummy memory cell in each of the memory strings; and
a controller configured to control application of voltages to the gates of the nonvolatile memory cells through the word lines, such that during an operation to read data from a group of the nonvolatile memory cells connected to a word line that is adjacent to the dummy word line, a read voltage is applied to the word line that is adjacent to the dummy word line while a first voltage is applied to the dummy word line, and a second voltage is applied to the other word lines, the first voltage being higher than the second voltage.

9. The memory system according to claim 8, wherein
during the operation to read data from the group of the nonvolatile memory cells, the read voltage is applied to the word line that is adjacent to the dummy word line while the first voltage is applied to the dummy word line and the second voltage is applied to the other word lines, in response to determining that the operation to read data from the group of the nonvolatile memory cells results in an error that is not correctable by error correction coding.

10. The memory system according to claim 8, wherein
during the operation to read data from the group of the nonvolatile memory cells, the read voltage is applied to the word line that is adjacent to the dummy word line while the first voltage is applied to the dummy word line and the second voltage is applied to the other word lines, in response to determining that the group of the nonvolatile memory cells has undergone erase and program operations a number of times that exceed a predetermined number.

11. The memory system according to claim 8, wherein
during an operation to read data from another group of the nonvolatile memory cells connected to a first word line, which is one of the word lines not adjacent to the dummy word line, the read voltage is applied to the first word line while the first voltage is applied to a second line that is adjacent to the first word line and the second voltage is applied to the other word lines.

12. The memory system according to claim 11, wherein the second word line is located on a side of the first word line that is closer to the dummy word line.

13. The memory system according to claim 8, wherein
if data stored in the dummy memory cells are first data, the read voltage is applied to the word line that is adjacent to the dummy word line while applying a third voltage that is higher than the second voltage to the dummy word line, and
if data stored in the dummy memory cells are second data, the read voltage is applied to the word line that is adjacent to the dummy word line while applying a fourth voltage that is higher than the third voltage to the dummy word line.

14. The memory system according claim 13, wherein
the controller maintains a table that associates voltages to be applied to the dummy word line with data stored in the dummy memory cells.

15. In a memory system having multiple memory strings each including a plurality of nonvolatile memory cells connected serially between first and second selection transistors, each memory string including a dummy memory cell adjacent to the first selection transistor and each nonvolatile memory cell configured to store more than one bit of data, and a plurality of word lines, each word line connected to agate of a different memory cell in each of the memory strings, the word lines including a dummy word line connected to a gate of the dummy memory cell in each of the memory strings, a method of controlling voltages applied to the word lines during an operation to read data from a group of the nonvolatile memory cells connected to a word line that is adjacent to the dummy word line, comprising:
applying a read voltage to the word line that is adjacent to the dummy word line while applying a first voltage to the dummy word line and a second voltage to the other word lines,
wherein the first voltage is higher than the second voltage.

16. The method of claim 15, further comprising:
determining that the operation to read data from the group of the nonvolatile memory cells results in an error that is not correctable by error correction coding.

17. The method of claim 15, further comprising:
determining that the group of the nonvolatile memory cells has undergone erase and program operations a number of times that exceed a predetermined number.

18. The method of claim 15, further comprising:
applying the read voltage to a first word line, which is one of the word lines not adjacent to the dummy word line while applying the first voltage to a second line that is adjacent to the first word line and the second voltage to the other word lines.

19. The method of claim 18, wherein the second word line is located on a side of the first word line that is closer to the dummy word line.

20. The method of claim 15, further comprising:
if data stored in the dummy memory cells are first data, applying the read voltage to the word line that is adjacent to the dummy word line while applying a third voltage that is higher than the second voltage to the dummy word line; and
if data stored in the dummy memory cells are second data, applying the read voltage to the word line that is adjacent to the dummy word line while applying a fourth voltage that is higher than the third voltage to the dummy word line.
